(19) United States
(12) Patent Application Publication
(10) Pub. No.: US 2015/0295148 A1
(43) Pub. Date: Oct. 15, 2015

(54) Package Substrate and Package Structure of Light Emitting Diode and Fabrication Thereof

(71) Applicant: XIAMEN SANAN OPTOELECTRONICS TECHNOLOGY CO., LTD., Xiamen (CN)

(72) Inventor: TE-LING HSIA, Xiamen (CN)

(73) Assignee: XIAMEN SANAN OPTOELECTRONICS TECHNOLOGY CO., LTD., Xiamen (CN)

(21) Appl. No.: 14/748,393

(22) Filed: Jun. 24, 2015

Related U.S. Application Data
(63) Continuation of application No. PCT/CN2014/071051, filed on Jan. 22, 2014.

(30) Foreign Application Priority Data
Apr. 19, 2013 (CN) 201310137420.X

(51) Int. Cl. H01L 33/54; H01L 33/00; H01L 33/36; H01L 33/48; H01L 33/62; H01L 33/56; H01L 33/22

(52) U.S. Cl. CPC H01L 33/54; H01L 33/56; H01L 33/005; H01L 33/22; H01L 33/486; H01L 33/62; H01L 33/36; H01L 2933/0033; H01L 2933/0016; H01L 2933/005; H01L 2933/0066

(57) ABSTRACT

A package substrate of a flip-chip light emitting diode applicable to eutectic bonding process, including a substrate body with a first surface, having thereon distributed with at least one unit, wherein the unit corresponds to a light emitting diode core grain and has a first region and a second region that are electrically isolated; and a groove structure between the two regions, wherein a top opening width of the groove structure is less than a width of the core grain to be packaged. The structure and method can reduce failures in the further substrate removal and surface roughening processes in existing flip-chip light-emitting diode of eutectic bonding process as a result of the distance between the chip and the substrate being too small to fill the under-fill at bottom.

### CROSS-REFERENCE TO RELATED APPLICATIONS

The present application is a continuation of, and claims priority to, PCT/CN2014/071051 filed on Jan. 22, 2014, which claims priority to Chinese Patent Application No. 201310137420.X filed on Apr. 19, 2013. The disclosures of these applications are hereby incorporated by reference in their entirety.

### BACKGROUND

Flip-chip package has been widely applied in mass production of light emitting diode for its certified excellent heat dissipation characteristic and good component mechanical strength. And application of flip-chip package technology in light emitting diode has become an important topic in industry. Application of flip-chip package technology in light emitting diode is mainly divided into the following two methods: Au-stub bumping process and eutectic bonding process. In Au-stub bumping process, the Au-stub bumping is firstly planted over the package substrate with relative position of the Au-stub bumping on the plate same as that of the chip electrode. Through later ultrasound pressing, the chip electrode and the Au-stub bumping on the package substrate have an electric connection. The advantages of this method are low requirement for the package substrate and flexible process while the disadvantages include high machine cost, slow production and high overall production cost in consideration of high-cost of Au-stub bumping and high precision of chip alignment. In eutectic bonding process, the selected eutectic metal is fabricated on the chip through evaporating or sputtering. The chip is pre-fit over the package substrate through low-temperature scaling powder. The chip is connected to the package substrate through reflow at melting point higher than that of the eutectic metal. The advantages of this method are low metal cost, fast production and low precision requirement of machine. But it has high requirements for flatness of package substrate and process precision. In addition, removal of growth substrate from the light emitting diode is a good method to effectively increase luminous efficiency of the flip-chip light emitting diode. However, in flip-chip package, the gap between the chip and the package substrate significantly influences the yield for removal of growth substrate.

### SUMMARY

The present disclosure provides package substrate and package structure of a flip-chip light emitting diode applicable to eutectic bonding process and fabrication method thereof, which solves the failure of further substrate removal and surface roughening in existing flip-chip light emitting diode of eutectic bonding process for the distance between the chip and the substrate is too small to fill the under-fill at bottom.

The present disclosure provides a package substrate of the flip-chip light emitting diode applicable to eutectic bonding process, comprising a substrate body with a first surface, distributed with at least one unit, in which, the unit corresponds to a light emitting diode core grain to be packaged and has a first region and a second region that are electrically isolated; and a groove structure between the two regions, in which, the top opening width is less than that of the light emitting diode core grain to be packaged.

In some embodiments, the groove structure at least has one side opening located at the side wall of the substrate body.

In some embodiments, section shape of the groove structure is rectangle, inverted-trapezoid, inverted triangle or arc.

In some embodiments, height difference of the groove structure is between 50 μm and 300 μm.

In some embodiments, the top opening width of the groove structure is between 100 μm and 1000 μm.

In some embodiments, when the groove structure is rectangle or inverted-trapezoid, the defined package substrate comprises first surfaces, second surfaces and third surfaces, in which, the second surface, at relative height, is located below the first surface and the second surface is between the two first surfaces, and the third surface is connected to the first surface and the second surface. It is easy to understand that the two second surfaces and the third surface comprise a groove structure.

In some embodiments, when the groove structure is rectangle or inverted-trapezoid, the angle of intersection between the second surface and the third surface is between 45 degrees and 90 degrees.

In some embodiments, the substrate body can be Si, AlN, Al₂O₃, epoxy molding compound (EMC), etc.

The present disclosure provides a package structure of the flip-chip light emitting diode applicable to eutectic bonding process, comprising a substrate body with a first surface, distributed with at least one unit, in which, the unit corresponds to a light emitting diode core grain to be packaged and has a first region and a second region that are electrically isolated; a groove structure between the two regions, in which, the top opening width is less than that of the light emitting diode core grain to be packaged, and the groove structure at least has one side opening located at the side wall of the substrate body; a first conductive layer in the first region; a second conductive layer in the second region; a light emitting diode chip with a first electrode and a second electrode, in which, a gap is between the two electrodes; the first conductive layer and the first electrode are para-positioned and die-bonding connected, so are the second conductive layer and the second electrode; an under-fill that is filled into the gap between the first electrode and the second electrode and the groove structure.

The present disclosure also provides a fabrication method of the package structure of the flip-chip light emitting diode, comprising: providing a substrate body with a first surface, distributed with at least one unit, in which, the unit corresponds to a light emitting diode core grain to be packaged and has a first region and a second region that are electrically isolated; forming an opening over the first surface of the substrate body and a groove structure between the two regions, in which, the top opening width of the groove structure is less than that of the light emitting diode core grain to be packaged; the groove structure at least has one side opening located at the side wall of the substrate body for fabrication of the package substrate; forming a first conductive layer in the first region; forming a second conductive layer in the second region; providing a light emitting diode with a first electrode and a second electrode, in which, a gap is between the two electrodes; para-positioning the first conductive layer and the first electrode, so doing the second conductive layer and the second electrode; die-bonding the light emitting diode over the package substrate with flip-chip package process; and filling the under-fill into the gap between the first electrode and the second electrode and the groove structure, thus forming a package structure of the light emitting diode.

In some embodiments, a top opening is formed over the first surface of the package substrate body through diamond cutter, yellow-light photo masking, dry/wet etching, etc.

In some embodiments, in the light emitting diode packaged over the package substrate through flip-chip package, the growth substrate can be further removed through laser lifting-off.

In some embodiments, after removal of the growth substrate, the exposed surface can be further roughened.

The package substrate disclosed in present disclosure can be applied in the flip-chip light emitting diode for height difference between the first surface and the second surface can effectively avoid poor contact during chip die bonding, which may cause component failure. At the same time, filling of the under-fill into the gap between the first electrode and the second electrode and the groove structure can prevent future laser lifting-off of the growth substrate from damaging the chip. Lastly, surface roughening of the epitaxial layer improves luminous efficiency of the light emitting diode.

### BRIEF DESCRIPTION OF THE DRAWINGS

FIG. 1A is a section view of the package substrate according to Embodiment 1 of the present disclosure.

FIG. 1B is a top view of the package substrate as shown in FIG. 1A.

FIG. 2A is a section view of the package substrate according to Embodiment 2 of the present disclosure.

FIG. 2B is a top view of the package substrate as shown in FIG. 2A.

FIG. 3 is a sectional view of a first fabrication step of the flip-chip light emitting diode according to some embodiments;

FIG. 4 illustrates a second step;

FIG. 5 illustrates a third step;

FIG. 6 illustrates a fourth step.

### IN THE DRAWINGS

100: package substrate; 00′: package substrate; 101: substrate body; 102: first surface; 103: second surface; 104: third surface; 105A: first conductive layer; 105B: second conductive layer; 106: groove; 107: under-fill; 201: light emitting diode; 202: growth substrate; 203: epitaxial layer; 204: roughened surface; 205A: first electrode; 205B: second electrode; W1: width of the two first surfaces adjacent to the second surface; W2: width of the second surface; d: height difference between the first surface and the second surface; θ: angle of intersection between the second surface and the third surface.

### DETAILED DESCRIPTION

To solve problems of the package substrate over the flip-chip light emitting diode in eutectic process, the following embodiments provide a package substrate of the flip-chip light emitting diode applicable to eutectic bonding process and fabrication method thereof, which also avoid damage to chip during further removal of the growth substrate. Detailed description will be given to the package substrate and application method thereof in combination with embodiments and drawings.

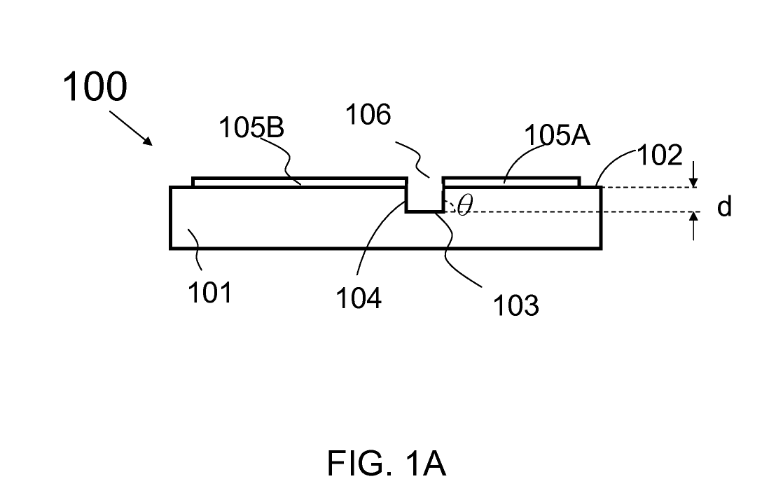

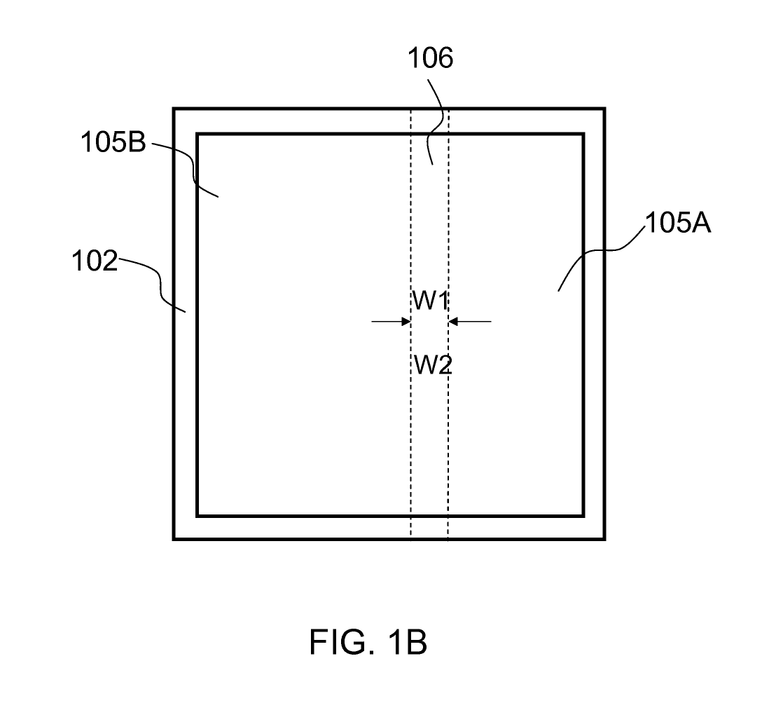

Refer to FIG. 1A-FIG. 1B. FIG. 1A is a section view of the package substrate according to Embodiment 1 of the present disclosure and FIG. 1B is a top view of the package substrate as shown in FIG. 1A. A package substrate 100, comprising: a substrate body 101, with a first surface 102, distributed with at least one unit, in which, each unit corresponds to a light emitting diode core grain and has a first region and a second region that are electrically isolated. As shown in FIG. 1A, the groove structure appears a rectangular section and is between two regions, in which, the top opening width W1 is less than that of the core grain to be packaged. As shown in FIG. 1B, two sides of the groove structure are at the side wall of the substrate body.

In this embodiment, the groove structure appears a rectangular section. The first conductive layer 105A is in the first region and the second conductive layer 105B is in the second region. The substrate body comprises a second surface 103, which, at relative height, is located below the first surface and the second surface is between the two first surfaces; the third surface 104 connects to the first surface and the second surface respectively, in which, the first surface 102, the second surface 103 and the third surface 104 form a groove 106.

In this embodiment, the first surface 102 and the second surface 103 are not co-plane, height difference d of which is 50 μm-300 μm but is not limited within such range. This height difference can effectively solve the known eutectic failure during eutectic process due to poor flatness of the substrate. The top opening width W1 of the groove 106 is between 100 μm and 1000 μm. The bottom opening width W2 of the groove 106 equals to the top opening width W1 of the groove 106. The angle of intersection θ between the second surface and the third surface is 90 degrees but is not limited to this value. In addition, the substrate body 101 can be AlN or other materials.

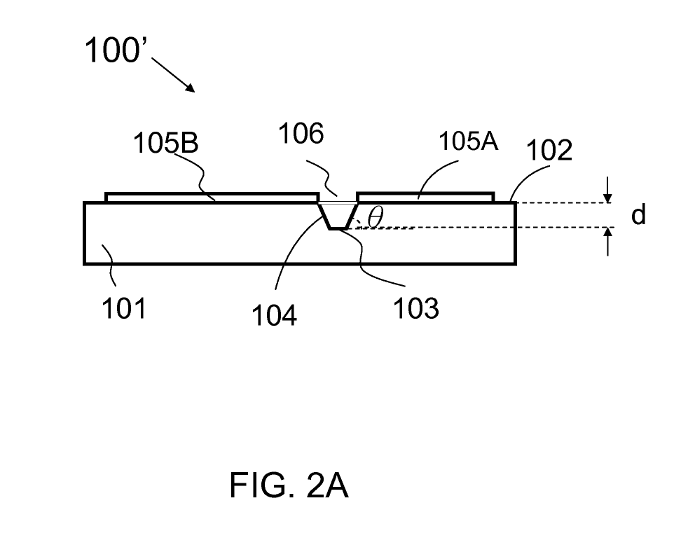

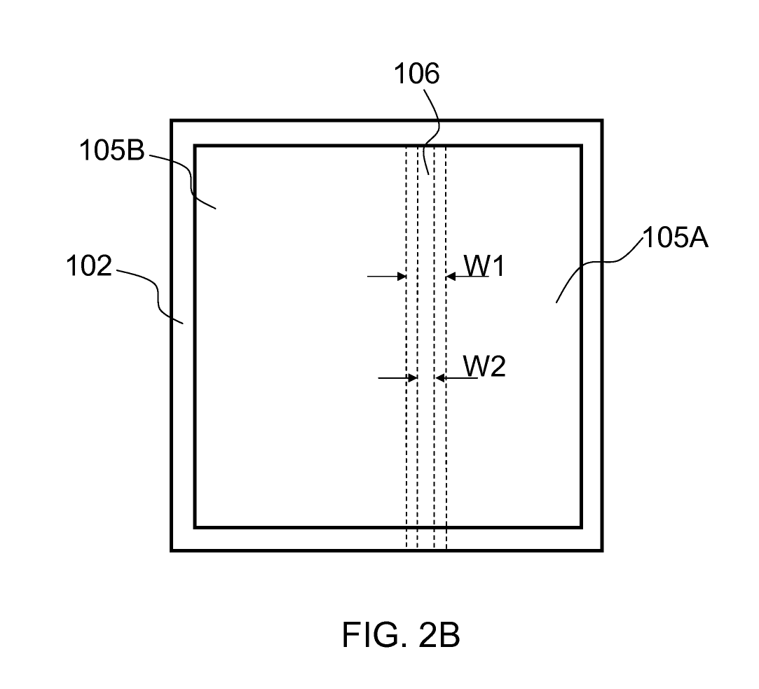

Refer to FIG. 2A-FIG. 2B. FIG. 2A is a section view of the package substrate according to Embodiment 2 of the present disclosure and FIG. 2B is a top view of the package substrate as shown in FIG. 2A. A package substrate 100′, comprising: a substrate body 101, with a first surface 102, distributed with at least one unit, in which, each unit corresponds to a light emitting diode core grain and has a first region and a second region that are electrically isolated. As shown in FIG. 2A, the groove structure appears a rectangular section and is between two regions, in which, the top opening width W1 is less than that of the core grain to be packaged. As shown in FIG. 2B, the opening at one side of the groove structure is at the side wall of the substrate body.

In this embodiment, the groove structure appears an inverted-trapezoid section. The first conductive layer 105A is in the first region and the second conductive layer 105B is in the second region. The substrate body comprises a second surface 103, which, at relative height, is located below the first surface and the second surface is between the two first surfaces; the third surface 104 connects to the first surface and the second surface respectively, in which, the first surface 102, the second surface 103 and the third surface 104 form a groove 106.

In this embodiment, the first surface 102 and the second surface 103 are not co-plane, height difference d of which is 50 μm-300 μm but is not limited within such range. The top opening width W1 of the groove 106 is between 100 μm and 1000 μm. The bottom opening width W2 of the groove 106 is less than the top opening width W1 of the groove 106. The angle of intersection θ between the second surface and the third surface is between 45 degrees and 90 degrees but is not limited to such range.

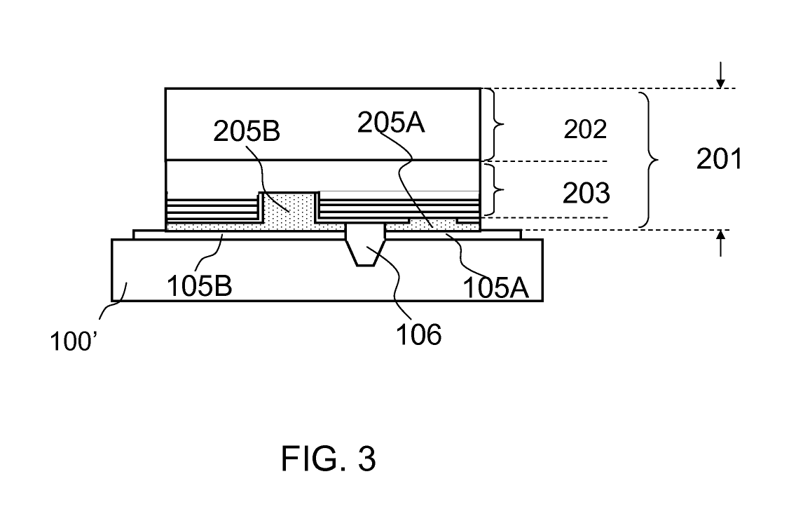

Refer to FIGS. 3-6, the section views of some fabrication steps of the package structure of flip-chip light emitting diode according to the present disclosure. Referring to FIG. 3, provide a sapphire (Al₂O₃) substrate body 100′ with a first surface 102, a second surface 103 and a third surface 104, in which, the third surface is connected to the first surface and the second surface; form an opening over the first surface of the substrate body with diamond cutter to form a groove structure with the second surface and the third surface; and fabricate a first conductive layer over the first surface; and fabricate a first conductive layer 105A and a second conductive layer 105B in the first region and the second region respectively. Provide a light emitting diode chip 201, comprising: a growth substrate 202, an epitaxial layer 203, a first electrode 205A and a second electrode 205B, in which, a gap is between the two electrodes; para-position the first conductive layer 105A and the first electrode 205A, so do the second conductive layer 105B and the second electrode 205B, and die bond the light emitting diode over the package substrate 100′ via flip-chip package process.

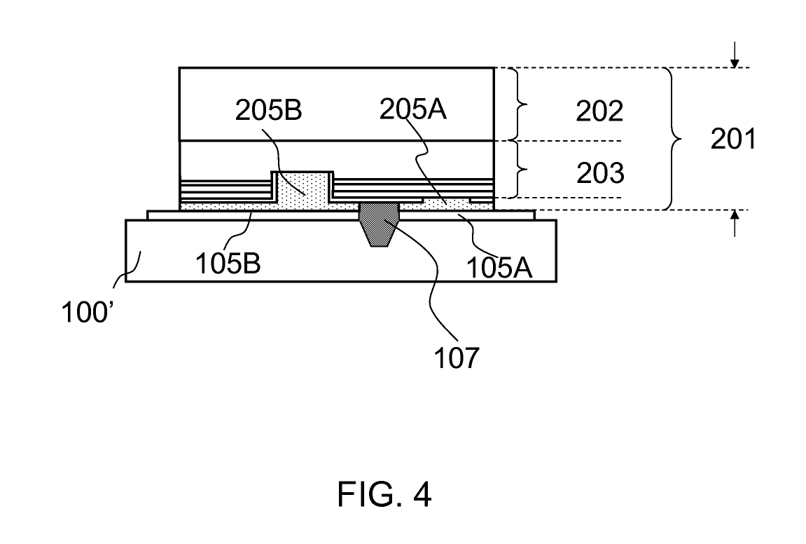

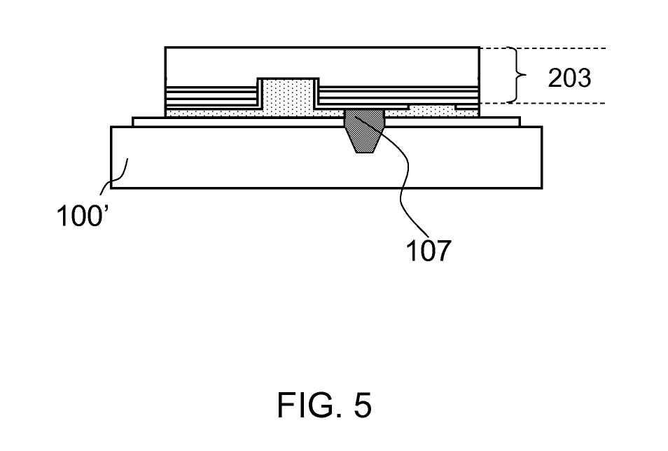

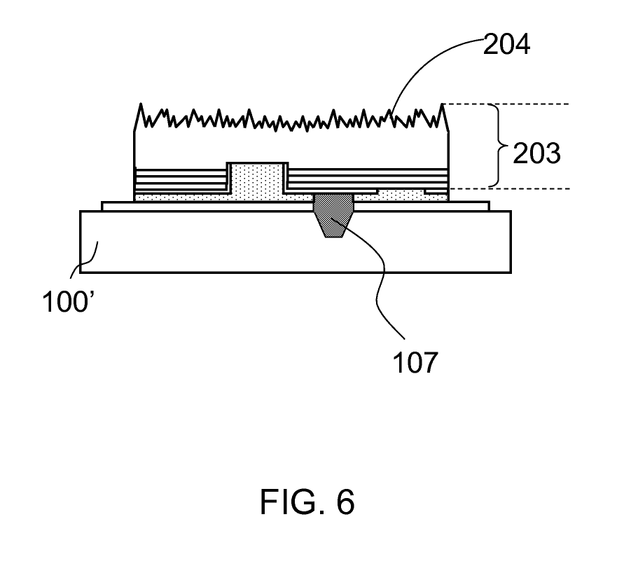

Referring to FIG. 4, fill the under-fill 107 into the gap between the first electrode and the second electrode and the groove structure, in which, the under-fill can be epoxy resin, silica gel or their combination. Preferably, this embodiment adopts silica gel. Referring to FIG. 5, remove the growth substrate 202 over the light emitting diode chip 201 through laser lifting-off process to expose surface of the epitaxial layer 203 of the light emitting diode chip 201. Formation of the groove 106 and filling and curing of the under-fill 107 can effectively avoid damage to the epitaxial layer 203 from stress change during laser lifting-off of the growth substrate 202 from the light emitting diode chip 201. Referring to FIG. 6, after removal of the growth substrate 202, process the light-emitting surface of the exposed epitaxial layer 203 via chemical etching process to form a roughened surface 204, thus further improving efficiency of the light emitting diode.

As known from the above embodiments, the package substrate and the package structure of the light emitting diode in the present disclosure can effectively solve the eutectic failure problem due to poor flatness of the substrate during flip-chip process. Further, after the light emitting diode is die-bonded over the package substrate, by filling an under-fill into the groove structure of the package substrate, damage to the chips from further laser lifting-off of the growth substrate can be eliminated. And final surface roughening increases luminous efficiency of the light emitting diode.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A package substrate of light emitting diode, comprising:
a substrate body with a first surface, having thereon distributed at least one unit, wherein the unit corresponds to a light emitting diode core grain to be packaged and has a first region and a second region that are electrically isolated; and
a groove structure between the first and second regions having a top opening width less than a width of the light emitting diode core grain to be packaged.

2. The package substrate of claim 1, wherein the groove structure at least has one side opening located at a side wall of the substrate body.

3. The package substrate of claim 1, wherein a section shape of the groove structure is rectangle, inverted-trapezoid, inverted triangle, or arc.

4. The package substrate of claim 1, wherein a height difference of the groove structure is between 50 μm and 300 μm.

5. The package substrate of claim 1, wherein a top opening width of the groove structure is between 100 μm and 1000 μm.

6. The package substrate of claim 1, wherein a section shape of the groove structure is rectangle or inverted-trapezoid, the package substrate has a second surface and a third surface, wherein the second surface is lower than the first surface, and the third surface is connected to the first surface and the second surface, and wherein an angle of intersection between the second surface and the third surface is between 45 degrees and 90 degrees.

7. A package structure of light emitting diode, comprising:
a substrate body with a first surface, having thereon distributed at least one unit, wherein the unit corresponds to a light emitting diode core grain to be packaged and has a first region and a second region that are electrically isolated;
a groove structure between the first and second regions having a top opening width less than a width of the light emitting diode core grain to be packaged, wherein the groove structure at least has one side opening located at a side wall of the substrate body;
a first conductive layer in the first region;
a second conductive layer in the second region;
a light emitting diode chip with a first electrode and a second electrode, wherein a gap is between the first and second electrodes;
wherein the first conductive layer and the first electrode, and the second conductive layer and the second electrode are respectively para-positioned and die-bonding connected; and
an under-fill is filled into the gap between the first electrode and the second electrode and the groove structure.

8. The package structure of claim 7, wherein a section shape of the groove structure is rectangle, inverted-trapezoid, inverted triangle, or arc.

9. The package structure of claim 7, wherein a height difference of the groove structure is between 50 μm and 300 μm.

10. The package structure of claim 7, wherein a top opening width of the groove structure is between 100 μm and 1000 μm.

11. The package structure of claim 7, wherein a section shape of the groove structure is rectangle or inverted-trapezoid, the package substrate has a second surface and a third surface, wherein the second surface is lower than the first surface, and the third surface is connected to the first surface and the second surface, and wherein an angle of intersection between the second surface and the third surface is between 45 degrees and 90 degrees.

12. A fabrication method of a package structure of a light emitting diode, comprising:
providing a substrate body with a first surface having thereon distributed at least one unit, wherein the unit corresponds to a light emitting diode core grain to be packaged and has a first region and a second region that are electrically isolated;
forming an opening over the first surface of the substrate body and a groove structure between the two regions, wherein a top opening width of the groove structure is less than a width of the light emitting diode core grain to be packaged; the groove structure at least has one side located at a side wall of the substrate body for fabrication of the package substrate;
forming a first conductive layer in the first region;
forming a second conductive layer in the second region;
providing a light emitting diode with a growth substrate, an epitaxial layer, a first electrode and a second electrode, in which, a gap is between the two electrodes;
para-positioning the first conductive layer and the first electrode, and the second conductive layer and the second electrode, respectively; and die bonding the light emitting diode over the package substrate via a flip-chip package process; and
filling an under-fill into the gap between the first electrode and the second electrode and the groove structure, thereby forming the package structure of the light emitting diode.

13. The fabrication method of claim 12, wherein the under-fill comprises at least one of an epoxy resin, or silica gel.

14. The fabrication method of claim 12, wherein after filling the under-fill into the gap between the first electrode and the second electrode and the groove structure, a lifting-off process is used to remove the growth substrate of the light emitting diode to expose the epitaxial layer.

15. The fabrication method of claim 14, wherein the lifting-off process comprises laser lifting-off.

16. The fabrication method of claim 15, further comprising, after removal of the growth substrate, roughening an exposed surface of the epitaxial layer.

17. The fabrication method of claim 12, wherein a height difference of the groove structure is between 50 μm and 300 μm.

18. The fabrication method of claim 12, wherein a top opening width of the groove structure is between 100 μm and 1000 μm.

19. The fabrication method of claim 12, wherein a section shape of the groove structure is rectangle or inverted-trapezoid, the package substrate has a second surface and a third surface, wherein the second surface is lower than the first surface, and the third surface is connected to the first surface and the second surface, and wherein an angle of intersection between the second surface and the third surface is between 45 degrees and 90 degrees.
